(19) United States
(12) Patent Application Publication
(10) Pub. No.: US 2026/0231546 A1
(43) Pub. Date: Aug. 6, 2026

(54) SEMICONDUCTOR PACKAGE INCLUDING DAM STRUCTURE

(71) Applicant: Samsung Electronics Co., Ltd., Suwon-si (KR)

(72) Inventor: Kosuke Hareyama, Suwon-si (KR)

(21) Appl. No.: 19/356,559

(22) Filed: Oct. 13, 2025

(30) Foreign Application Priority Data
Feb. 4, 2025 (JP) 2025-016798
May 19, 2025 (KR) 10-2025-0064327

(51) Int. Cl. H10F 39/00

(52) U.S. Cl. CPC H10F 39/804; H10F 39/811

(57) ABSTRACT

A semiconductor package is provided. The semiconductor package includes a package substrate having a recess portion in a central portion, an image sensor chip on the recess portion of the package substrate, a transparent substrate spaced apart from the image sensor chip in a height direction, and a dam structure disposed on the image sensor chip and disposed between the image sensor chip and the transparent substrate, wherein an outer side of the dam structure is encapsulated, wherein the dam structure is on a non-pixel region located on an upper surface of the image sensor chip and a mounting surface of the package substrate is at a same height as the upper surface of the image sensor chip.

### CROSS-REFERENCE TO RELATED APPLICATION(S)

This application claims benefit of priority to Japanese Patent Application No. 2025-016798 filed on Feb. 4, 2025, in the Japan Patent Office, and Korean Patent Application No. 10-2025-0064327 filed on May 19, 2025, in the Korean Intellectual Property Office, the disclosures of which are incorporated herein by reference in their entirety.

### BACKGROUND

In a semiconductor package used for a solid-state imaging device or the like, a transparent substrate (e.g., encapsulating glass) may be used to protect an image sensor chip (or semiconductor chip) mounted on a package substrate.

Generally, in a semiconductor package having a ball grid array (BGA) structure or the like, a dam structure may be provided to suppress influences due to a transparent substrate (e.g., flare, fogging due to heat generation of the semiconductor chip, or the like). The dam structure may be formed of a resin for maintaining the transparent substrate in a position spaced apart from an image sensor chip in a height direction (e.g., stacking direction). In addition, a molded portion (or molded resin) may be disposed to surround a periphery of the dam structure in the semiconductor package configured in this manner. In the semiconductor package configured in this manner, an encapsulating space (or cavity) hermetically encapsulated may be formed by the transparent substrate, the dam structure, and the molded portion.

In an image sensor chip, a pixel region may be provided. In the pixel region, optical elements such as an on-chip lens, a color filter, or the like are disposed, and a non-pixel region disposed to surround the pixel region. A dam structure provided to maintain a transparent substrate may be generally disposed only in the non-pixel region not to overlap the pixel region.

### SUMMARY

The present disclosure relates to semiconductor packages.

In a semiconductor package, it is desired to make the non-pixel region as small as possible to secure a larger pixel region area (for example, to improve yield of an image sensor chip). When a non-pixel region area is formed to be small, a dam width of the dam structure disposed in the non-pixel region may not be sufficiently secured, resulting in a decrease in strength (or decrease in support capacity) of the dam structure. When strength of the dam structure decreases, the dam structure may be easily collapsed in a height direction. Accordingly, the height of the dam structure may be reduced, thereby making it difficult to secure a certain distance between a transparent substrate and an image sensor chip.

In related art, a semiconductor package has a ball grid array (BGA) structure for reducing a dam width of a dam structure on a non-pixel region by disposing a dam structure on the non-pixel region and an outer peripheral side of a substrate located outside the non-pixel region. The dam structure may be employed to reduce the dam width on the non-pixel region while maintaining entirely the dam width of the dam structure to the same extent as before.

In the related art, the non-pixel region on the image sensor chip and an upper surface (or mounting surface) of the substrate, in which the dam structure is disposed, are disposed to change positions thereof in the height direction. Specifically, the upper surface of the substrate is disposed in a lower position than the non-pixel region. Because of this, a step difference in the height direction is formed between the non-pixel region and the upper surface of the substrate.

To address the above-mentioned step difference and achieve other purposes, the techniques discussed herein adopt one or more of the following approaches in forming the dam structure.

In forming the dam structure, one resin material, which may be a constituent material of the dam structure, is disposed to surround an outer peripheral surface of the image sensor chip, and a gap between the outer peripheral surface of the image sensor chip and a molded portion surrounding therearound is filled. Then, another resin material is disposed to overlap to span the non-pixel region and an upper portion of the one resin material. The resin materials are stacked in plural in this manner, a dam structure of a predetermined height extending from the upper surface of the substrate to a position higher than the non-pixel region of the image sensor chip is formed.

As described above, in forming the dam structure in the related art, a process in which the one resin material is disposed to fill the gap between the outer peripheral surface of the image sensor chip and the molded portion surrounding therearound, and then another resin material is overlapped thereon, is performed to have an increase in the number of processes for forming the dam structure.

In addition, another resin material is disposed to span on the one resin material to fill the gap and to span the non-pixel region. Therefore, a contact state (or support state) between the one resin material and another resin material is greatly affected by a size of a width, arrangement, properties, or the like of each of the resin materials. Therefore, it is difficult to accurately control the contact state between the resin materials, and it becomes difficult to stably maintain a height of the dam structure. For example, when the dam structure collapses due to weight of the transparent substrate itself, and a distance between the transparent substrate and the image sensor chip cannot be maintained at a predetermined level or higher, flare of the transparent substrate will have an excessive effect on the image sensor chip, resulting in a deterioration in pixel quality.

The techniques discussed herein consider the circumstances described above, and aim to provide a semiconductor package securing strength of a dam structure while expanding a pixel region of an image sensor chip.

To address the problems discussed above and otherwise known, the techniques in the present disclosure provides one or more of the following features.

A semiconductor package may include a package substrate having a recess portion recess in a central portion; an image sensor chip disposed on the recess portion of the package substrate; a transparent substrate disposed at a predetermined distance from the image sensor chip in a height direction; and a dam structure disposed between the image sensor chip and the transparent substrate on the image sensor chip, wherein an outer side of the dam structure is encapsulated, wherein the dam structure is disposed on a non-pixel region located on an upper surface of the image sensor chip and a mounting surface of the package substrate located on approximately the same height as the upper surface.

The semiconductor package may have a first pad portion disposed in the non-pixel region; a second pad portion disposed on the mounting surface; and a conductive wire connected to the first pad portion and the second pad portion.

The semiconductor package may have an adhesive layer disposed in a gap between an inner side surface of the recess portion and the image sensor chip, wherein the adhesive layer comprises a resin material having 100 Pa·s or less.

A width of the dam structure disposed on the non-pixel region may be 60% or less of a width of the non-pixel region.

A reflectivity of the dam structure may be 5% or less.

The semiconductor package may include a stopper having a ring shape and surrounding a peripheral of a pixel region of the image sensor chip.

The semiconductor package may include a plating layer disposed on an inner side surface of the recess portion and a bottom surface of the recess portion, and a thermal via extending from the bottom surface of the recess portion to a bottom surface of the package substrate.

The dam structure may have a first portion formed of a resin material and disposed to contact the non-pixel region and the mounting surface, and a second portion disposed above the first portion and having a width, smaller than a width the first portion.

An upper end portion of the second portion may be disposed above a molded portion covering an outer periphery of the dam structure, and the second portion may comprise a resin material having higher moisture permeability than the first portion.

A semiconductor package may include a package substrate having a recess portion recess in a central portion; an image sensor chip disposed on the recess portion of the package substrate; a plating layer disposed on an inner side surface of the recess portion and a bottom surface of the recess portion; a transparent substrate disposed at a predetermined distance from the image sensor chip in a height direction; and a dam structure disposed on the image sensor chip and disposed between the image sensor chip and the transparent substrate, wherein an outer side of the dam structure is encapsulated, wherein the dam structure is disposed on a non-pixel region located on an upper surface of the image sensor chip and a mounting surface of the package substrate located on the same height as the upper surface.

The plating layer may include a material having higher thermal conductivity than a resin material constituting the package substrate.

The semiconductor package may have a thermal via extending from the bottom surface of the recess portion to a bottom surface of the package substrate.

The plating layer may be disposed in the thermal via.

The plating layer may be in contact with a portion of a side surface of the thermal via.

The semiconductor package may include an adhesive layer disposed in a gap between the inner side surface of the recess portion and the image sensor chip, wherein the plating layer is disposed between the adhesive layer and the inner side surface of the recess portion.

The semiconductor package may include a die bond disposed in a gap between the bottom surface of the recess portion and the image sensor chip, wherein the plating layer is disposed between the die bond and the bottom surface of the recess portion.

A semiconductor package may include a package substrate having a recess portion recess in a central portion; an image sensor chip disposed on the recess portion of the package substrate; a transparent substrate disposed on the image sensor chip; and a dam structure disposed on the image sensor chip and disposed between the image sensor chip and the transparent substrate, wherein an outer side of the dam structure is encapsulated, wherein the dam structure includes an insertion portion protruding downward from a lower end portion and inserted into the recess portion.

The insertion portion of the dam structure may be disposed between the recess portion of the package substrate and the image sensor chip.

The insertion portion of the dam structure may be in contact with an adhesive layer disposed in a gap between an inner side surface of the recess portion and the image sensor chip.

The semiconductor package may have a plating layer disposed on an inner side surface of the recess portion and a bottom surface of the recess portion, wherein at least a portion of the plating layer is disposed on a side surface of the insertion portion of the dam structure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor package according to at least one implementation.

FIG. 2 is a cross-sectional view of FIG. 1, taken along line II-II.

FIG. 3 is an enlarged view of a portion taken by broken line III illustrated in FIG. 2.

FIG. 4 is an enlarged view of a portion taken by broken line IV illustrated in FIG. 2.

FIG. 5 is a view illustrating a method for manufacturing a semiconductor package according to at least one implementation.

FIG. 6 is a view illustrating a method for manufacturing a semiconductor package according to at least one implementation.

FIG. 7 is a cross-sectional view illustrating a semiconductor package of an Example Implementation 1.

FIG. 8 is a cross-sectional view illustrating a semiconductor package of an Example Implementation 2.

FIG. 9 is a cross-sectional view illustrating a semiconductor package of an Example Implementation 3.

FIG. 10 is a cross-sectional view illustrating a semiconductor package of an Example Implementation 4.

FIG. 11 is a cross-sectional view illustrating a semiconductor package of an Example Implementation 5.

FIG. 12 is a cross-sectional view illustrating a semiconductor package an Example Implementation 6.

### DETAILED DESCRIPTION

Hereinafter, with reference to the attached drawings, one or more implementations will be described in detail. In the drawings below, the same reference numerals indicate the same components, and in the drawings, a size of each of the components may be exaggerated for clarity and convenience of explanation. In addition, the implementations described below are merely illustrative, and various modifications are possible from such implementations.

Hereinafter, the terms “on,” “above,” or “on or above” may include not only those directly above in contact, but also those directly above in non-contact. Similarly, the terms “below” or “on or below” may include not only those directly below in contact, but also those directly below in non-contact.

A singular expression may include a plural expression, unless the context clearly indicates that it is singular. In addition, when a portion is said to “comprise,” “include,” “provide,” or “have” a component, this may mean that other components may be additionally included, rather than excluding other components, unless otherwise specifically stated.

With respect to operations constituting a method, when an order is explicitly stated or when there is no other description, the operations constituting the method may be performed in an appropriate order. It may not be necessarily limited to an order of the operations described. All examples or illustrative terms may be used only to explain technical ideas, and the scope is not limited by the examples or illustrative terms, unless otherwise specified by the claims.

In the following descriptions, when ordinal numerals such as “first” and “second” are attached for explanation, they may be used for convenience and do not specify any order, unless specifically stated.

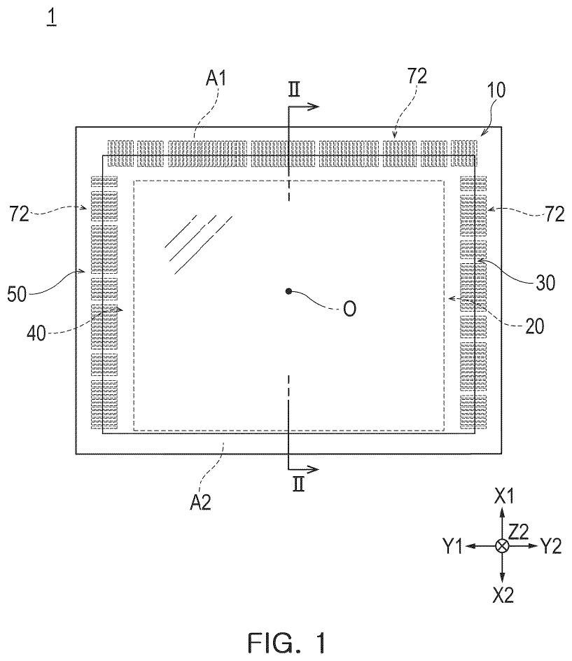

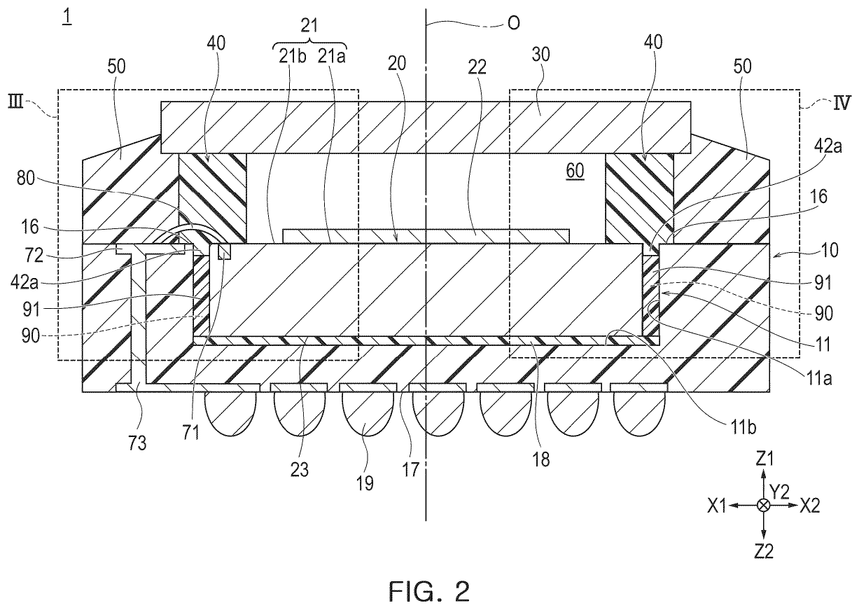

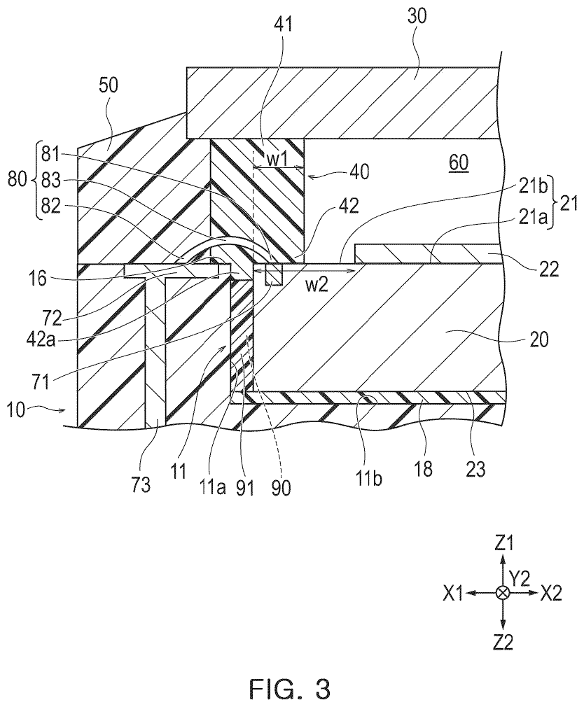

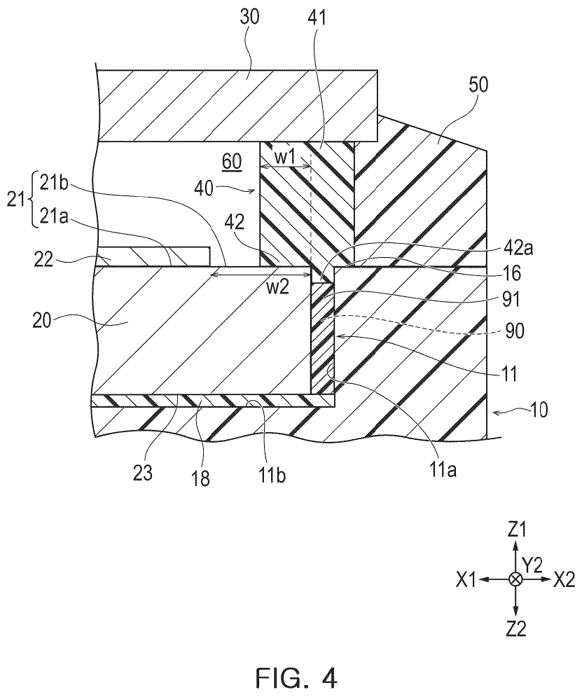

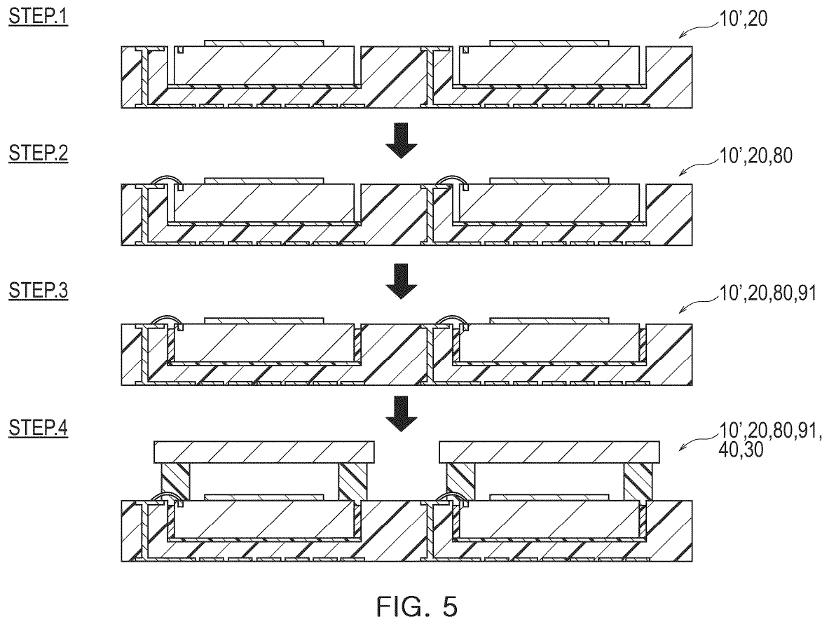

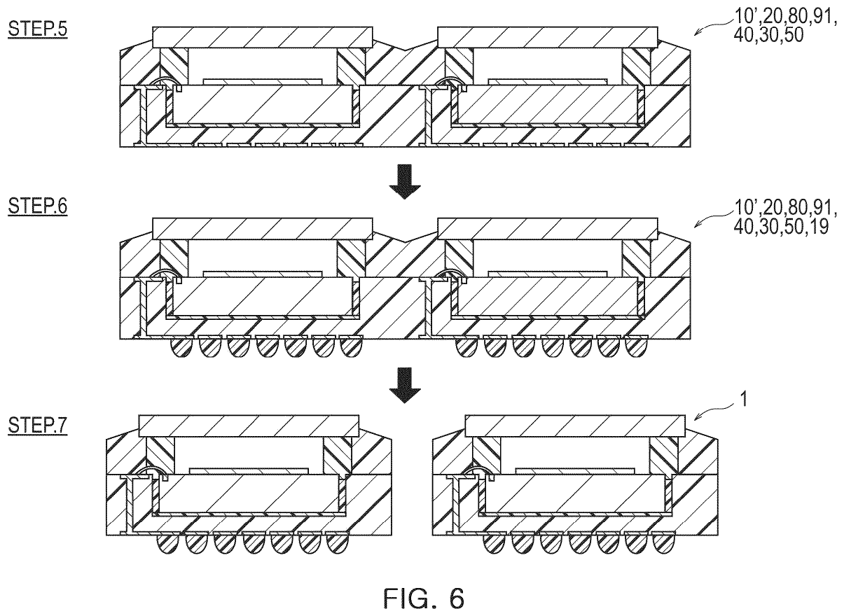

FIG. 1 is a schematic plan view of a semiconductor package 1 according to at least one implementation as viewed from an upper surface side of a transparent substrate 30. FIG. 2 is a cross-sectional view (cross-sectional view in the height direction) of the semiconductor package 1 illustrated in FIG. 1, taken along line II-II. FIG. 3 is an enlarged view of a portion taken by broken line III illustrated in FIG. 2, and FIG. 4 is an enlarged view of a portion taken by broken line IV illustrated in FIG. 2. FIGS. 5 and 6 are views briefly illustrating each step of a method for manufacturing a semiconductor package 1.

In this specification, a direction in which an image sensor chip 20 is stacked on a package substrate 10 may be referred to as a “height direction (or stacking direction)” (up-down direction in FIG. 2). In each drawing, an arrow (Z1) indicates an upper side in the height direction, and an arrow (Z2) indicates a lower side in the height direction. A direction (left-right direction in FIG. 2), orthogonal to the height direction, indicated by an arrow (X1-X2) may be referred to as a “width direction.” A direction (left-right direction in FIG. 1), orthogonal to each of the height direction and the width direction, may be referred to as an arrow (Y1-Y2) in each drawing. In the description of each member, an “upper surface (upper surface side)” means an element located on the upper side in the height direction, and a “lower surface (lower surface side)” and a “bottom surface (bottom surface side)” mean elements located on the lower side in the height direction.

As illustrated in FIGS. 1 and 2, a semiconductor package 1 may be configured as a semiconductor package 1 having a package substrate 10 having a central portion of a recess structure, an image sensor chip 20 disposed on a recess portion 11 on the package substrate, a transparent substrate 30 disposed at a predetermined distance from the image sensor chip 20 in the height direction, and a dam structure 40 disposed between the image sensor chip 20 and the transparent substrate 30 on the image sensor chip 20, wherein an outer side of the dam structure 40 is encapsulated. In some examples, the recess portion 11 including an inner side surface 11a and a bottom surface 11b can define a concave shape.

As illustrated in FIG. 2, the semiconductor package 1 may be configured as, for example, a ball grid array (BGA) structure having a wiring pad portion 73 provided on the package substrate 10, and a solder ball 19 electrically connected to the wiring pad portion 73 and enabling mounting of the package substrate 10 on a motherboard (not illustrated).

The semiconductor package 1 may transmit incident light that is incident from an upper surface side of the transparent substrate 30 through the transparent substrate 30, and may receive light from the image sensor chip 20 mounted on the package substrate 10. The image sensor chip 20 may be configured as, for example, an imaging element such as a CMOS sensor, a CCD sensor, or the like. When the image sensor chip 20 is configured as the imaging element, an optical element 22 such as a micro lens, a color filter, or the like may be disposed in a pixel region of the image sensor chip 20.

In some implementations, on an upper surface 21 of the image sensor chip 20, a pixel region 21a corresponds to a region in which the optical element 22 is disposed. In addition, on the upper surface 21 of the image sensor chip 20, a non-pixel region 21b corresponds to a region located on an outer side (outer side away from a center O in the width direction) than the pixel region 21a and in which the optical element 22 is not disposed.

A protective film (for example, a SiO₂ film) may be provided on the upper surface 21 of the image sensor chip 20.

In the package substrate 10, a space around the image sensor chip 20 may be encapsulated by the transparent substrate 30, the dam structure 40, and a molded portion 50 covering an outer periphery of the dam structure 40. Therefore, an encapsulating space (or cavity) 60 hermetically encapsulated may be defined around the image sensor chip 20.

The recess portion 11 provided in the semiconductor package 1 may be provided in a certain range including the center O in a plane direction of the semiconductor package 1. The center O in the plane direction may correspond to an intersection point in which a center in the width direction (arrow (X1-X2) direction) illustrated in FIG. 1 and a center in a direction (arrow (Y1-Y2) direction), orthogonal to the width direction, intersect with each other.

As illustrated in FIG. 2, the recess portion 11 may have a cross-sectional recessed shape in the height direction of the package substrate 10.

The image sensor chip 20 may be formed to have a dimension in the width direction, smaller than that of the recess portion 11.

The image sensor chip 20 may be disposed within the recess portion 11. As described above, since the image sensor chip 20 may have a width, smaller than a width of the recess portion 11, a predetermined gap 90 may be formed between a side surface of the image sensor chip 20 and an inner side surface 11a of the recess portion 11.

The package substrate 10 has a mounting surface 16 (uppermost surface) on which a second pad portion 72 described below is disposed. The mounting surface 16 may be located on an outer peripheral side of the recess portion 11.

As illustrated in FIG. 1, the package substrate 10 may have an approximately rectangular shape when viewed in the plan view. In the present implementation, the second pad portion 72 may be formed on three sides among four sides of the semiconductor package 1, and the second pad portion 72 may not be formed on the remaining one side. Hereinafter, a side on which the second pad portion 72 is formed may be referred to as a “pad side A1,” and a side on which the second pad portion 72 is not formed may be referred to as a “non-pad side A2.”

The mounting surface 16 may be disposed on approximately the same height as the upper surface 21 of the image sensor chip 20 in which the pixel region 21a and the non-pixel region 21b are located.

The package substrate 10 and the image sensor chip 20 may be fixed by a die bond 18 disposed between a bottom surface 17 of the package substrate 10 and a bottom surface 23 of the image sensor chip 20.

As illustrated in FIG. 2, the transparent substrate 30 may be supported by the dam structure 40, and may be located in a position spaced upwardly from the image sensor chip 20 by a predetermined distance in the height direction.

A lower surface of the transparent substrate 30 may be located to face the upper surface 21 of the image sensor chip 20.

As illustrated in FIGS. 3 and 4, the dam structure 40 has an upper end portion 41 located to contact the lower surface of the transparent substrate 30, and a lower end portion 42 located to contact the non-pixel region 21b and the mounting surface 16.

The dam structure 40 may extend in a straight line with a substantially constant cross-sectional area (or cross-sectional shape) between the upper end portion 41 and the lower end portion 42. The dam structure 40 may have an insertion portion 42a protruding downward from the lower end portion 42, and may be inserted into the recess portion 11.

As illustrated in FIG. 2, the dam structure 40 may be disposed on the non-pixel region 21b located on the upper surface 21 of the image sensor chip 20, and the mounting surface 16 of the package substrate 10 located on approximately the same height as the upper surface 21.

In general, when securing a larger area of a pixel region in a semiconductor package, an attempt for reducing a width of a non-pixel region may be made. When the width of the non-pixel region is reduced, a width of a dam structure that may be disposed on the non-pixel region may not be formed not to be small. When the width of the dam structure is reduced, strength of the dam structure may not be sufficiently secured, making it difficult to maintain a transparent substrate in a stable height position.

In the semiconductor package 1 of the present implementation, as described above, the dam structure 40 may be disposed on the non-pixel region 21b and the mounting surface 16 disposed on an outer peripheral side of the non-pixel region 21b. Therefore, even in a case in which a width of the non-pixel region 21b is formed to be small, a width of the dam structure 40 may be made to be large by an amount disposed on the mounting surface 16. Therefore, it is possible to secure strength of the dam structure 40 while attempting to expand an area of the pixel region 21a by reducing the width of the non-pixel region 21b.

In addition, in the semiconductor package 1 of the present implementation, the non-pixel region 21b and the mounting surface 16, in which the dam structure 40 is disposed, may be located on substantially the same height. For this reason, the lower end portion 42, which serves as a base portion entirely supporting the dam structure 40, may be in contact with the non-pixel region 21b and the mounting surface 16, respectively, in a stable state in which no step difference is formed between the non-pixel region 21b and the mounting surface 16. Therefore, the semiconductor package 1 may prevent the dam structure 40 from collapsing or the like, and may stably maintain the transparent substrate 30 disposed on the upper end portion 41 of the dam structure 40 in a predetermined position in the height direction.

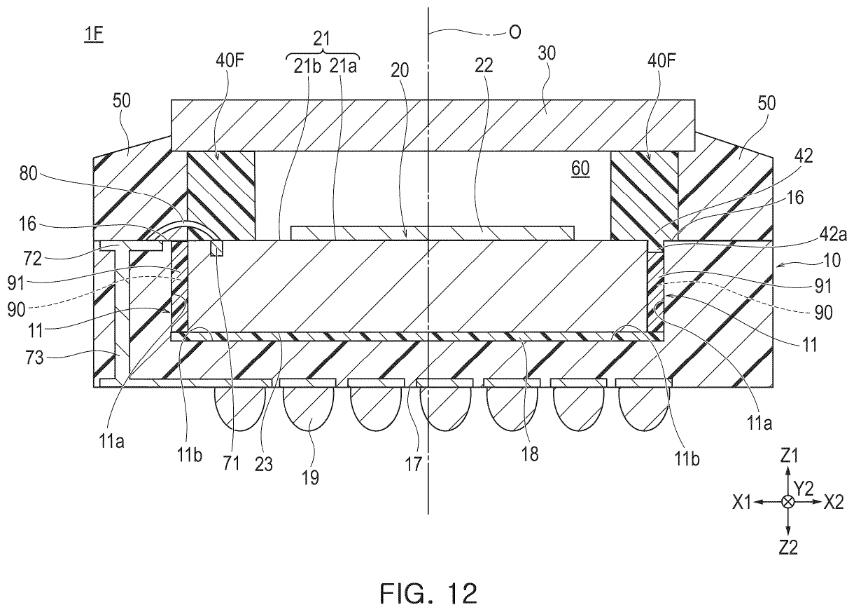

In the present implementation, as illustrated in FIGS. 1 to 4, the dam structure 40 may be disposed on the non-pixel region 21b and the mounting surface 16 on both the pad side A1 and the non-pad side A2. However, as described in Example Implementations below, the dam structure 40 may be disposed on the non-pixel region 21b and the mounting surface 16 only in the non-pad side A2, as shown, for example in FIG. 12.

As illustrated in FIGS. 2 to 4, the semiconductor package 1 may have a first pad portion 71 disposed in the non-pixel region 21b, a second pad portion 72 disposed in the mounting surface 16, and a conductive wire 80 connected to the first pad portion 71 and the second pad portion 72.

As illustrated in FIG. 3, the second pad portion 72 may be electrically connected to the solder ball 19 disposed on a bottom surface 17 side of the package substrate 10 via the wiring pad portion 73 provided on the package substrate 10.

The conductive wire 80 may have one end portion 81 connected to the first pad portion 71, the other end portion 82 connected to the second pad portion 72, and an intermediate portion 83 extending between the one end portion 81 and the other end portion 82 and of which at least portion extends into the dam structure 40.

As described above, the non-pixel region 21b and the mounting surface 16 may be disposed on substantially the same height. Therefore, the one end portion 81 of the conductive wire 80 and the other end portion 82 of the conductive wire 80 may be also disposed on substantially the same height. Therefore, the conductive wire 80 may have little or no misalignment in the height direction between the one end portion 81 and the other end portion 82.

For example, when there is a misalignment in the height direction between the non-pixel region 21b and the mounting surface 16, a misalignment in the height direction may also occur between one end portion 81 and the other end portion 82 of the conductive wire 80. In such a case, the conductive wire 80 may be disposed to arch upward in a central portion from one end portion side toward the other end portion side. As an example, when the mounting surface 16 is disposed in a position lower than the non-pixel region 21b, the conductive wire 80 may be disposed to arch upward in a central portion from the one end portion 81 toward the other end portion 82. When the conductive wire 80 is disposed in this manner, connection reliability near each of the end portions 81 and 82 of the conductive wire 80 may be deteriorated.

In addition, when the conductive wire 80 is extended to a longer distance depending on a difference in the height direction between the mounting surface 16 and the non-pixel region 21b, an increase in electrical resistance of the conductive wire 80 may be caused.

In addition, when heat is generated from the image sensor chip 20 and the conductive wire 80 expands due to the heat, a stress pulling up the image sensor chip 20 by the conductive wire 80 may be generated. In this case, due to a difference between a coefficient of linear expansion of the dam structure 40 comprised of a resin material and a coefficient of linear expansion of the conductive wire 80 comprised of a metal material, the conductive wire 80 may extend more significantly compared to the dam structure 40. In addition, since the dam structure 40 does not expand to follow the extension of the conductive wire 80, a greater stress may be applied to the vicinity of the one end portion 81 of the conductive wire 80 connected to the first pad portion 71. In particular, when there is a large difference in height between the mounting surface 16 and the non-pixel region 21b, and the conductive wire 80 is extended over a long distance accordingly, an expansion amount of the conductive wire 80 may entire increase, such that a larger stress may be applied near the one end portion 81 of the conductive wire 80. As a result, bending may occur in the pixel region 21a of the image sensor chip 20 on which the first pad portion 71 is disposed, or the one end portion 81 of the conductive wire 80 becomes easy to peel off from the first pad portion 71.

In the semiconductor package 1, the conductive wire 80 may be connected to each of the pad portions 71 and 72 in a state in which there is little misalignment in the height direction between the one end portion 81 and the other end portion 82. Therefore, it is possible to prevent the conductive wire 80 from being disposed as if it is being lowered from the one end portion 81 to the other end portion 82. In addition, since a misalignment in height between the one end portion 81 and the other end portion 82 of the conductive wire 80 may be small, a distance between each end portions 81 and 82 may be made small, and an overall length of the conductive wire 80 may be made short. Therefore, the semiconductor package 1 may improve connection reliability between each of the end portions 81 and 82 of the conductive wire 80 and each of the pad portions 71 and 72, and may also prevent an increase in electrical resistance of the conductive wire 80.

As illustrated in FIGS. 2 to 4, the semiconductor package 1 may have an adhesive layer 91 disposed in the gap 90 between the inner side surface 11a of the recess portion 11 and the image sensor chip 20.

As described above, the image sensor chip 20 may be formed to have a dimension, smaller than a dimension of the recess portion 11 in a width direction. Therefore, in a manufacturing process of the semiconductor package 1, when mounting the image sensor chip 20 on the package substrate 10 (STEP. 1 of FIG. 5 described below), the image sensor chip 20 may be inserted to be disposed on the recess portion 11. When a width of the image sensor chip 20 is formed to be greater than a width of the recess portion 11, the image sensor chip 20 may not be inserted to be disposed on the recess portion 11. Therefore, the image sensor chip 20 may be manufactured such that the width of the image sensor chip 20 may be sufficiently smaller than the width of the recess portion 11 after considering a manufacturing tolerance. When the image sensor chip 20 is manufactured with a width size, as described above, the gap 90 may be formed between the image sensor chip 20 and the recess portion 11.

In the semiconductor package 1, the adhesive layer 91 may be formed by an adhesive filled in the gap 90. By providing the adhesive layer 91, the semiconductor package 1 may be designed to improve the connection strength between the image sensor chip 20 and the package substrate 10.

Since the gap 90 may be formed in a microscopic size, to densely spread the adhesive to a deeper position (position on a bottom surface 11b side of the recess portion 11) of the gap 90, it is necessary to adjust viscosity of a resin material (adhesive) constituting the adhesive layer 91 to increase fluidity during filling.

In consideration of the above points, in the present implementation, the adhesive layer 91 may comprise a resin material having 100 Pa·s or less.

When a viscosity of the resin material constituting the adhesive layer 91 is 300 Pa·s or less, the resin material may be sufficiently delivered to a deeper position in the gap 90 by utilizing a capillary phenomenon, and voids may be prevented from occurring in the resin material filled in the gap 90. Therefore, bonding strength between the image sensor chip 20 and the package substrate 10 may effectively increase.

More preferably, the viscosity of the resin material constituting the adhesive layer 91 is 70 Pa·s or more and 100 Pa·s or less, for example, considering a material or properties of the resin material used, a filling property for the gap 90, or the like.

As illustrated in FIG. 3 and FIG. 4, the insertion portion 42a extending into the gap 90 may be formed in the lower end portion 42 of the dam structure 40. For example, the insertion portion 42a may be disposed between the recess portion 11 of the package substrate 10 and the image sensor chip 20. The insertion portion 42a may be in contact with the image sensor chip 20 and the inner side surface 11a of the recess portion 11. In some implementations, the insertion portion 42a may also be in contact with the adhesive layer 91 disposed in the gap 90. A portion of the dam structure 40 in the gap 90 may be disposed to prevent formation of a space in the gap 90 in which a member is not be filled. Therefore, a degree of adhesion between the image sensor chip 20, the package substrate 10, and the dam structure 40 may be further improved.

As illustrated in FIGS. 3 and 4, a width w1 of the dam structure 40 disposed on the non-pixel region 21b may be formed to be 60% or less of a width w2 of the non-pixel region.

As described above, the width w1 of the dam structure 40 disposed on the non-pixel region 21b may be disposed to be 60% or less of the width w2 of the non-pixel region 21b, to achieve both expansion of an area of the pixel region 21a and securing of strength of the dam structure 40.

Each portion of the semiconductor package 1 may comprise, for example, materials, as described below. The materials illustrated below are illustrative, and are not limited thereto.

The package substrate 10 may include one ore more of, for example, polyimide, polyester, ceramic, epoxy, bismaleimidetriazine, phenol resin, alumina, aluminum nitride, beryllium oxide, silicon nitride, and other ceramics.

The image sensor chip 20 may comprise, for example, a silicon chip.

The transparent substrate 30 may include one or more of, for example, quartz glass, borosilicate glass, non-alkali glass, or the like.

The dam structure 40 may be comprised of, for example, a resin material (glass adhesive) such as an epoxy resin or the like.

The molded portion 50 may be comprised of, for example, an epoxy-based resin material (liquid encapsulating adhesive).

The conductive wire 80 may be comprised of, for example, a metal material such as copper, silver, gold, aluminum, or the like, or an alloy thereof. The same material may be used for the wiring pad portion 73.

The die bond 18 may be comprised of a known epoxy-based resin material.

The adhesive layer 91 may be comprised of, for example, an epoxy-based resin material (glass adhesive) prepared with a predetermined viscosity (100 Pa·s or less).

As described above, semiconductor package 1 according to the present implementation may have a package substrate 10 having a central portion of a recess structure, an image sensor chip 20 disposed on a recess portion 11 on the package substrate 10, a transparent substrate 30 disposed at a predetermined distance from the image sensor chip 20 in a height direction, and a dam structure 40 disposed between the image sensor chip 20 and the transparent substrate 30 on the image sensor chip 20, wherein an outer side of the dam structure 40 is encapsulated, wherein the dam structure 40 is disposed on a non-pixel region 21b located on an upper surface 21 of the image sensor chip and a mounting surface 16 of the package substrate 10 located on approximately the same height as the upper surface 21.

According to the semiconductor package 1 configured as described above, even in a case in which a width of the non-pixel region 21b is formed to be small, a width of the dam structure 40 may be made to be large by an amount disposed on the mounting surface 16. Therefore, it is possible to secure strength of the dam structure 40 while attempting to expand an area of the pixel region 21a by reducing the width of the non-pixel region 21b.

In addition, in the semiconductor package 1 of the present implementation, the non-pixel region 21b and the mounting surface 16, in which the dam structure 40 is disposed, may be located on substantially the same height. For this reason, the lower end portion 42, which serves as a base portion entirely supporting the dam structure 40, may be in contact with the non-pixel region 21b and the mounting surface 16, respectively, in a stable state in which no step difference is formed between the non-pixel region 21b and the mounting surface 16. Therefore, the semiconductor package 1 may prevent the dam structure 40 from collapsing or the like, and may stably maintain the transparent substrate 30 disposed on the upper end portion 41 of the dam structure 40 in a predetermined position in the height direction.

### Method for Manufacturing Semiconductor Package

With reference to FIGS. 5 and 6, a method for manufacturing a semiconductor package 1 according to at least one implementation may be outlined.

As illustrated in FIG. 5, an image sensor chip 20 may be disposed in a recess portion 11 of a package substrate 10′ (package substrate before slicing), and the package substrate 10′ and the image sensor chip 20 may be fixed by a die bond 18 (STEP. 1).

Next, a conductive wire 80 may be connected to each pad portion (71 and 72) (STEP. 2).

Next, an adhesive layer 91 may be formed in a gap 90 formed between an inner side surface 11a of the recess portion 11 and the image sensor chip 20 (STEP. 3). In this case, viscosity of a resin material constituting the adhesive layer 91 may be adjusted to 100 Pa·s or less, to smoothly fill the resin material in the gap 90.

Next, a dam structure 40 may be formed, and a transparent substrate 30 may be fixed (adhered) on the dam structure 40 (STEP. 4). In this process, a portion of the gap 90 formed between a non-pixel region 21b and a mounting surface 16 may be filled with a resin material constituting the dam structure 40, an insertion portion 42a in which a portion of the dam structure 40 is inserted into the gap 90 may be formed (see FIGS. 3 and 4).

As illustrated in FIG. 6, a molded portion 50 surrounding an outer periphery of the dam structure 40 may be formed (STEP. 5).

Next, a solder ball 19 may be mounted on a bottom surface 17 side of the package substrate 10′ (STEP. 6).

Next, the package substrate 10′ equipped with each component (20, 80, 91, 40, 30, 50, and 19) may be cut and sliced to manufacture a semiconductor package 1 (STEP. 7).

Next, a description will be given of an Example Implementation of the above-described implementation. In the description of each Example Implementation, descriptions of contents overlapping those already described in the above-described implementation will be omitted. In addition, components or elements that exhibit the same function and effect, etc. may be given the same component numbers and descriptions thereof will be omitted.

### Example Implementation 1

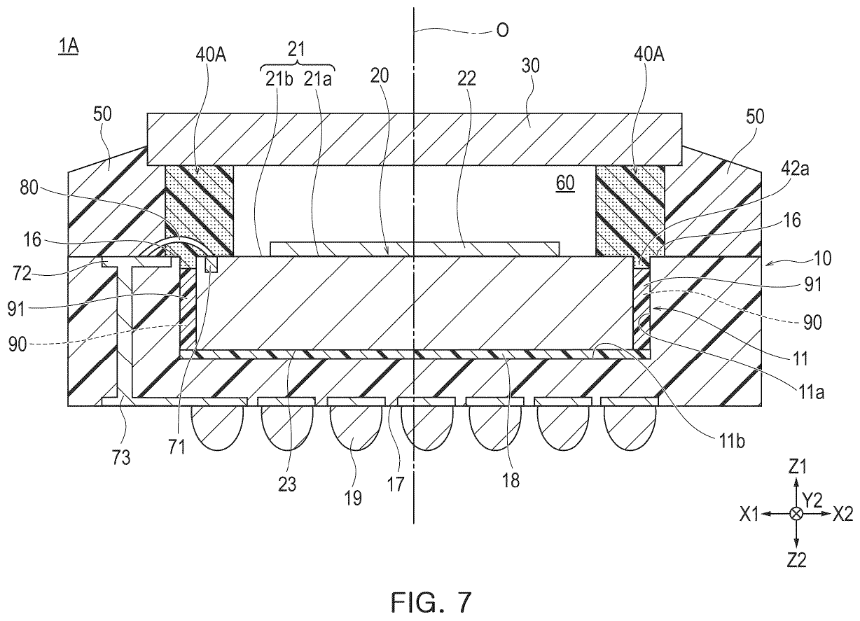

FIG. 7 illustrates a cross-sectional view of a semiconductor package 1A according to example implementation 1.

In the semiconductor package 1A, reflectivity (reflectivity of light) of a dam structure 40A may be formed to be 5% or less.

As described above, a conductive wire 80 may have an intermediate portion 83 that extends into the dam structure 40. In addition, one end portion 81 of the conductive wire 80 may be connected to a first pad portion 71 disposed on a non-pixel region 21b. Therefore, when viewed from an upper side of a transparent substrate 30 in plan view, the dam structure 40 and the conductive wire 80 may be disposed to partially overlap each other.

In a case in which the reflectivity of the dam structure 40A is configured to be 5% or less as in the present example implementation, even when incident light incident from an upper surface side of the transparent substrate 30 maintained in an upper end portion 41 of the dam structure 40A is reflected by the conductive wire 80 disposed in the dam structure 40A, an effect of flare on an outside of the dam structure 40A may be prevented. Therefore, occurrence of noise in an electric signal generated by an image sensor chip 20 may be prevented.

As a method for adjusting the reflectivity of the dam structure 40A to 5% or less, for example, coloring may be performed on a resin material constituting the dam structure 40A. As an example, a method of forming the dam structure 40A in black by adding a predetermined coloring agent (black particles such as carbon black) to the resin material may be adopted.

Considering a material, properties, or the like of the resin material used, it is more preferable that the reflectivity of the dam structure 40A be 3% or less, for example.

### Example Implementation 2

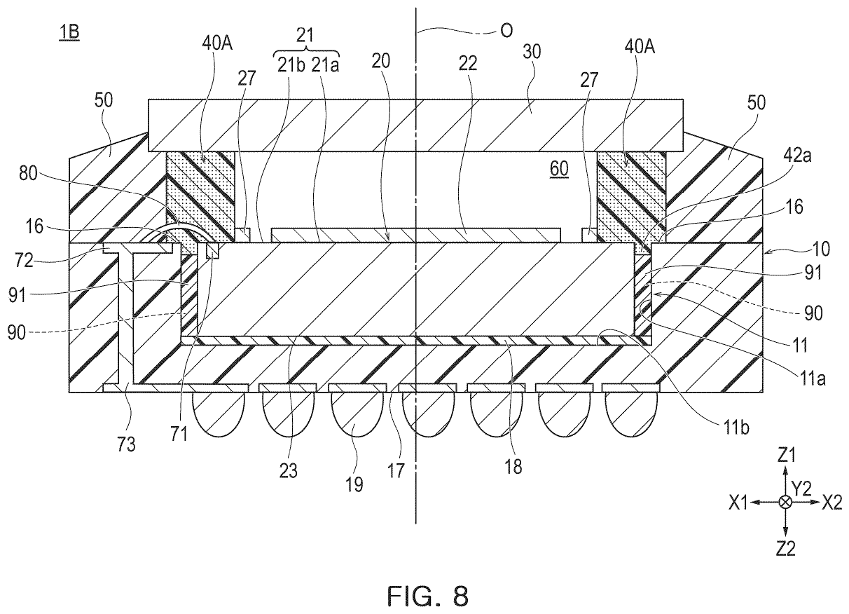

FIG. 8 illustrates a cross-sectional view of a semiconductor package 1B according to example implementation 2.

The semiconductor package 1B may have a stopper 27 having a ring shape and surrounding of a pixel region 21a of an image sensor chip 20. For example, the stopper 27 surrounds a periphery of the pixel region 21a. In a process for manufacturing the semiconductor package 1B, when forming a dam structure 40A (STEP. 4 of FIG. 5), the stopper 27 may be disposed to in a predetermined position on an upper surface 21 of the image sensor chip 20, to prevent a resin material forming the dam structure 40A from flowing toward the pixel region 21a. Therefore, it becomes possible to appropriately control a width of the dam structure 40A disposed on a non-pixel region 21b.

It is preferable that the stopper 27 be formed of a material having a low light reflectivity. As an example, the stopper 27 may be formed of the same material as the transparent substrate 30.

### Example Implementation 3

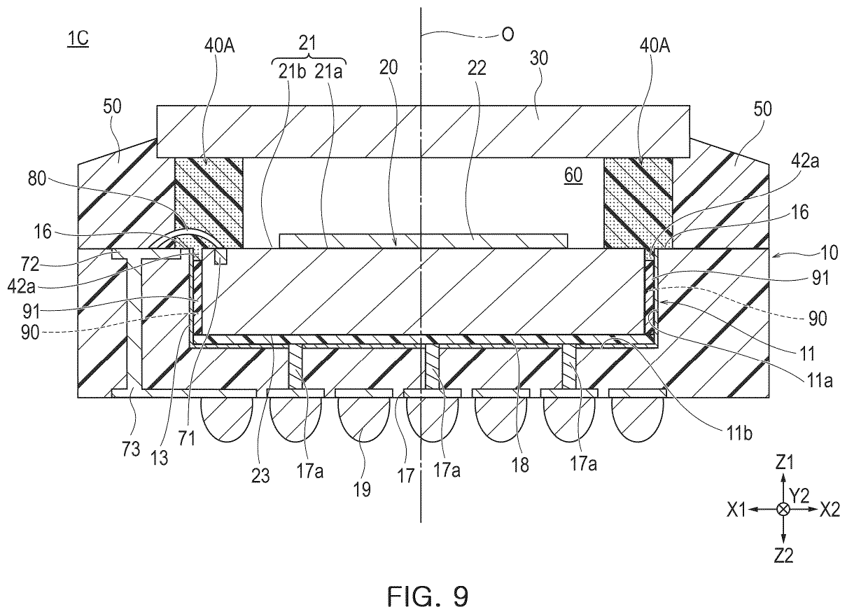

FIG. 9 illustrates a cross-sectional view of a semiconductor package 1C according to example implementation 3.

The semiconductor package 1C may have a plating layer 13 provided on an inner side surface 11a of a recess portion 11 and a bottom surface 11b of the recess portion 11, and a thermal via 17a extending from the bottom surface 11b of the recess portion 11 to a bottom surface 17 of a package substrate 10. For example, a plating layer 13 may be disposed between an inner side surface 11a of a recess portion 11 and an adhesive layer 91, and/or between a bottom surface 11b of the recess portion 11 and a die bond 18. A portion of the plating layer 13 disposed on the inner side surface 11a of the recess portion 11 may be in contact with an insertion portion 42a of a dam structure 40.

The plating layer 13 may comprise a metal material (e.g., copper plating or gold plating) having a higher thermal conductivity than a resin material constituting the package substrate 10. The thermal via 17a may be filled with a metal material (e.g., copper) having a higher thermal conductivity.

The semiconductor package 1C configured as described above may efficiently release heat from an image sensor chip 20 to the bottom surface 11b of the recess portion 11 by the plating layer 13 provided on each of the portions 11a and 11b of the recess portion 11 when heat is generated from the image sensor chip 20. In addition, the semiconductor package 1C may release heat moved to the bottom surface 11b of the recess portion 11 through the plating layer 13 to an outside of the package substrate 10 from the bottom surface 17 of the package substrate 10 through the thermal via 17a. Therefore, heat dissipation of the semiconductor package 1 may be effectively improved.

The plating layer 13 may be provided on the thermal via 17a in addition to the inner side surface 11a of the recess portion 11 and the bottom surface 11b of the recess portion 11. According to implementations, the plating layer 13 may be provided on a side surface of the thermal via 17a or may be in contact with at least a portion of the side surface of the thermal via 17a. The plating layer 13 may be also provided on the thermal via 17a to further improve heat dissipation of the semiconductor package 1C.

### Example Implementation 4

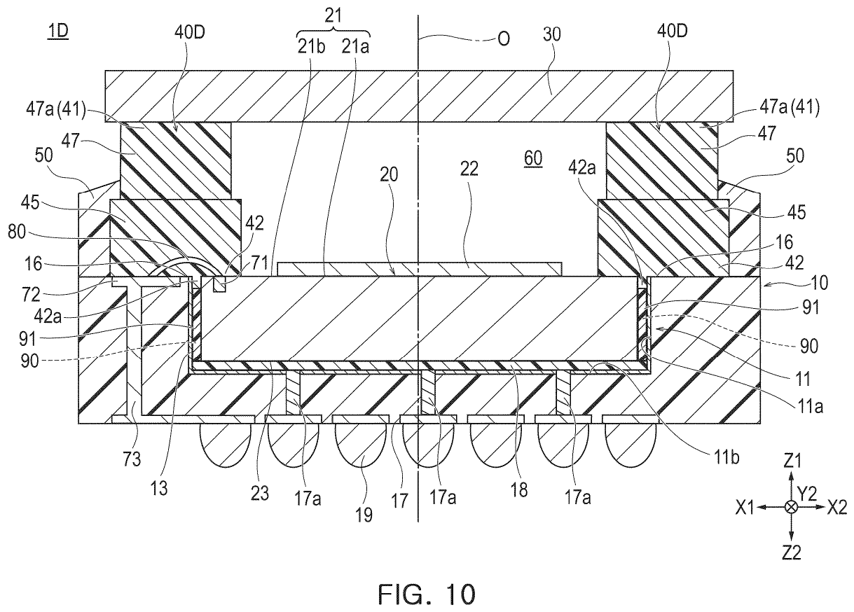

FIG. 10 illustrates a cross-sectional view of a semiconductor package 1D according to example implementation 4.

A dam structure 40D of the semiconductor package 1D may have a first portion 45 formed of a resin material disposed to contact a non-pixel region 21b and a mounting surface 16, and a second portion 47 disposed above the first portion 45 and having a smaller width than the first portion 45.

As illustrated in FIG. 10, a lower end portion of the first portion 45 (the same position as a lower end portion 42 of the dam structure 40D) may be disposed on the non-pixel region 21b and the mounting surface 16.

An upper end portion 47a of the second portion 47 (the same position as an upper end portion 41 of the dam structure 40D) may be in contact with a lower surface of a transparent substrate 30.

As described above, the dam structure 40D may have the first portion 45 and the second portion 47, stacked in the height direction. Therefore, a height of the dam structure 40D may be made higher. Therefore, a distance between an image sensor chip 20 and the transparent substrate 30 may be secured larger. Therefore, influence of flare generated from the transparent substrate 30 on the image sensor chip 20 may be more reliably prevented.

In addition, as described above, the dam structure 40D may be formed with a large width of the first portion 45 disposed on a lower side in the height direction. A molded portion 50 disposed on an outer side of the first portion 45 may be formed to be smaller in accordance with an increase in width of the first portion 45.

For example, in a reliability test or the like performed at a high temperature, when a thermal load is applied to the semiconductor package 1D, an internal pressure of an encapsulating space 60 may increase due to outgas accompanying reflow of the dam structure 40D, vapor generated by evaporating moisture contained in air existing in the encapsulating space 60, or the like. When such an increase in the internal pressure occurs, a stress may be generated between the dam structure 40D and the molded portion 50 toward an outside of the encapsulating space 60.

In the semiconductor package 1D, since a width of the molded portion 50 may be formed to be small as described above, a stress acting between the first portion 45 and the molded portion 50 may be reduced. Therefore, cracks or the like may be effectively prevented from occurring in the dam structure 40D and the molded portion 50. In addition, since a stress acting between the dam structure 40D and the molded portion 50 may be reduced, influence of this stress may be prevented from affecting an upper surface 21 (non-pixel region 21b) of the image sensor chip 20 contacting the first portion 45. Therefore, the semiconductor package 1D may also prevent cracks or the like from occurring in a protective film formed on the upper surface 21 of the image sensor chip 20 when a thermal load is applied.

The number of portions (portions corresponding to the first portion 45 and the second portion 47) constituting the dam structure 40D is not particularly limited. For example, it is also possible to configure one dam structure by overlapping three or more portions having different widths. In addition, a size of a width of each of the portions 45 and 47 is not particularly limited as long as the first portion 45 has a larger width than the second portion 47. In addition, the first portion 45 and the second portion 47 may be comprised of, for example, the same material as a material exemplified as a material of the dam structure 40 described above. The first portion 45 and the second portion 47 may be comprised of the same resin material, or may be comprised of different resin materials. In FIG. 10, the molded portion 50 may be formed to a position covering a side surface of the first portion 45 and a portion of a side surface of the second portion 47, but it may also be formed to a position covering the side surface of the first portion 45 and entirely the side surface of the second portion 47.

### Example Implementation 5

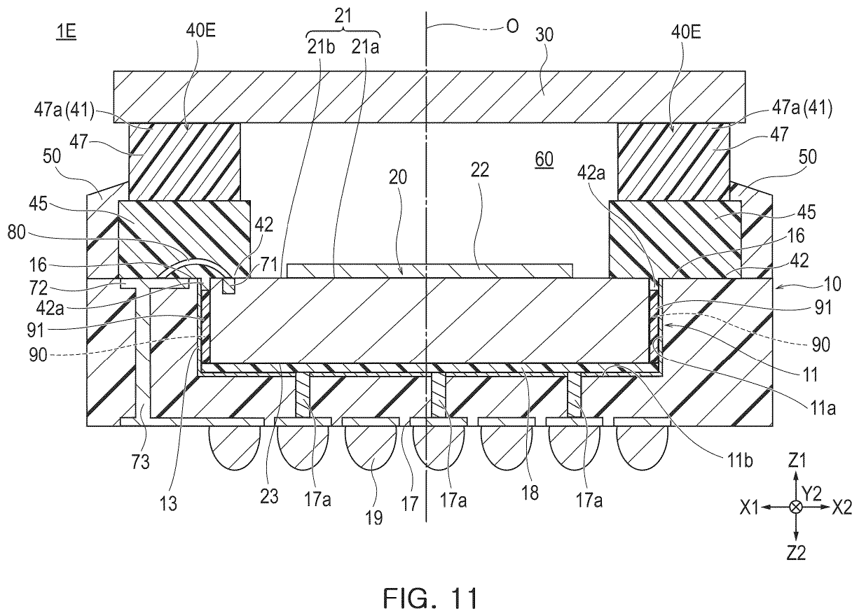

FIG. 11 illustrates a cross-sectional view of a semiconductor package 1E according to example implementation 5.

In a dam structure 40E of the semiconductor package 1E, an upper end portion 47a of a second portion 47 may be located above a molded portion 50 covering an outer periphery of the dam structure 40E.

In addition, the second portion 47 may be comprised of a resin material having higher moisture permeability than a first portion 45.

The second portion 47 may be comprised of, for example, a silicone resin or the like having relatively high moisture permeability. A specific material of the second portion 47 is not limited as long as it has higher moisture permeability than the resin material constituting the first portion 45.

In the semiconductor package 1E, the second portion 47 may be comprised of a resin material having high moisture permeability, and furthermore, the upper end portion 47a of the second portion 47 may be located above the molded portion 50. Therefore, when a thermal load is applied to the semiconductor package 1E and outgas or vapor is generated in an encapsulating space 60, the outgas or vapor may be released from the upper end portion 47a of the second portion 47 to an outside of the encapsulating space 60. Therefore, even when a thermal load is applied, the semiconductor package 1E may prevent peeling between the dam structure 40E and an image sensor chip 20, peeling of a transparent substrate 30 from the dam structure 40E, damage to the dam structure 40E, or the like.

### Example Implementation 6

FIG. 12 illustrates a cross-sectional view of a semiconductor package 1F according to example implementation 6.

As illustrated in FIG. 12, a dam structure 40F may be disposed on a non-pixel region 21b and a mounting surface 16 only on a non-pad side A2 (see FIG. 1). For example, a portion of a dam structure 40F disposed on a pad side A1 (see FIG. 1) may be disposed only on v non-pixel region 21b. This may be due to the following reasons.

In a semiconductor package having a ball grid array (BGA) structure, there may be cases in which a circuit element or the like is disposed separately on a pad side A1. Therefore, depending on product specifications of a semiconductor package 1, there may be cases in which it is not desirable to provide a dam structure 40 having a larger width disposed on the pad side A1 to span a non-pixel region 21b and a mounting surface 16. In addition, when the dam structure 40 formed on the pad side A1 is disposed on the non-pixel region 21b and the mounting surface 16, the dam structure 40 may be disposed with a larger width to spread outward, such that a width of a transparent substrate 30 supported by the dam structure 40 may increase in accordance with an increase in width.

The semiconductor package according to the techniques discussed herein has been described above through the implementations and the plurality of example implementations, but the techniques discussed herein are not limited to the contents described in the specification, and may be modified in an appropriate manner.

For example, in the present specification, a BGA structure is illustrated as an example of a structure of the semiconductor package, but is not limited thereto.

In addition, configurations described in the implementations herein may be arbitrarily and selectively combined as long as the effect exerted based on each configuration may not be impaired. For example, it is possible to arbitrarily and selectively incorporate each structure described in example implementations 1 to 5 into the semiconductor package 1F having the structure described in example implementation 6.

A semiconductor package according to at least one implementation aims to provide a semiconductor package in which a pixel region of an image sensor chip is expanded while strength of a dam structure is secured.

While example implementations have been illustrated and described above, it will be apparent to those skilled in the art that modifications and variations could be made without departing from the scope of the techniques discussed herein as defined by the appended claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above detailed description of the implementations of the present disclosure is not intended to limit the scope of the present disclosure. Rather, various modifications and improvements made by a person of ordinary skill in the art using the basic concepts of the present disclosure as defined in the following claims also fall within the scope of the present disclosure.

What is claimed is:

1. A semiconductor package comprising:
a package substrate having a recess portion in a central portion of the package substrate;
an image sensor chip on the recess portion of the package substrate;
a transparent substrate spaced apart from the image sensor chip in a height direction; and
a dam structure disposed on the image sensor chip and disposed between the image sensor chip and the transparent substrate, wherein an outer side of the dam structure is encapsulated,
wherein the dam structure is on a non-pixel region located on an upper surface of the image sensor chip, and a mounting surface of the package substrate is at a same height as the upper surface of the image sensor chip.

2. The semiconductor package of claim 1, comprising:
a first pad portion in the non-pixel region;
a second pad portion on the mounting surface; and
a conductive wire connected to the first pad portion and the second pad portion.

3. The semiconductor package of claim 1, comprising an adhesive layer in a gap between an inner side surface of the recess portion and the image sensor chip,
wherein the adhesive layer includes a resin material having a viscosity of 100 Pa·s or less.

4. The semiconductor package of claim 1, wherein a width of the dam structure on the non-pixel region is 60% or less of a width of the non-pixel region.

5. The semiconductor package of claim 1, wherein reflectivity of the dam structure is 5% or less.

6. The semiconductor package of claim 1, comprising a stopper having a ring shape, wherein the stopper surrounds a pixel region of the image sensor chip.

7. The semiconductor package of claim 1, comprising:
a plating layer on an inner side surface of the recess portion and a bottom surface of the recess portion, and
a thermal via that extends from the bottom surface of the recess portion to a bottom surface of the package substrate.

8. The semiconductor package of claim 1, wherein the dam structure has a first portion including a resin material,
wherein the first portion contacts the non-pixel region and the mounting surface, and wherein a second portion is above the first portion,
wherein a width of the second portion is smaller than a width the first portion.

9. The semiconductor package of claim 8, wherein an upper end portion of the second portion is above a molded portion covering an outer periphery of the dam structure, and
wherein the second portion comprises a resin material having higher moisture permeability than the first portion.

10. A semiconductor package comprising:
a package substrate having a recess portion recess in a central portion;
an image sensor chip on the recess portion of the package substrate;
a plating layer on an inner side surface of the recess portion and a bottom surface of the recess portion;
a transparent substrate spaced apart from the image sensor chip in a height direction; and
a dam structure disposed on the image sensor chip and disposed between the image sensor chip and the transparent substrate, wherein an outer side of the dam structure is encapsulated,
wherein the dam structure is on a non-pixel region located on an upper surface of the image sensor chip, and
wherein a mounting surface of the package substrate is at a same height as the upper surface of the image sensor chip.

11. The semiconductor package of claim 10, wherein the plating layer includes a material having higher thermal conductivity than a resin material constituting the package substrate.

12. The semiconductor package of claim 10, comprising a thermal via extending from the bottom surface of the recess portion to a bottom surface of the package substrate.

13. The semiconductor package of claim 12, wherein the plating layer is in the thermal via.

14. The semiconductor package of claim 13, wherein the plating layer is in contact with a portion of a side surface of the thermal via.

15. The semiconductor package of claim 10, comprising an adhesive layer in a gap between the inner side surface of the recess portion and the image sensor chip,
wherein the plating layer is between the adhesive layer and the inner side surface of the recess portion.

16. The semiconductor package of claim 10, comprising a die bond in a gap between the bottom surface of the recess portion and the image sensor chip,
wherein the plating layer is between the die bond and the bottom surface of the recess portion.

17. A semiconductor package comprising:
a package substrate having a recess portion in a central portion of the package substrate;
an image sensor chip on the recess portion of the package substrate;
a transparent substrate on the image sensor chip; and
a dam structure disposed on the image sensor chip and disposed between the image sensor chip and the transparent substrate, wherein an outer side of the dam structure is encapsulated,
wherein the dam structure includes an insertion portion that extends downward from a lower end portion of the dam structure, and the insertion portion is inserted into the recess portion.

18. The semiconductor package of claim 17, wherein the insertion portion of the dam structure is between the recess portion of the package substrate and the image sensor chip.

19. The semiconductor package of claim 18, wherein the insertion portion of the dam structure is in contact with an adhesive layer in a gap between an inner side surface of the recess portion and the image sensor chip.

20. The semiconductor package of claim 17, comprising a plating layer on an inner side surface of the recess portion and a bottom surface of the recess portion,
wherein at least a portion of the plating layer is on a side surface of the insertion portion of the dam structure.
